(19) United States
(12) Patent Application Publication
(10) Pub. No.: US 2010/0126577 A1
(43) Pub. Date: May 27, 2010

(54) GUIDED MODE RESONANCE SOLAR CELL

(75) Inventors: Mount-Learn Wu, Taoyuan (TW); Jenq-Yang Chang, Taoyuan (TW); Yun-Chih Lee, Taoyuan (TW); Chian-Fu Huang, Taoyuan (TW)

Correspondence Address: KIRTON AND MCCONKIE, 60 EAST SOUTH TEMPLE,, SUITE 1800, SALT LAKE CITY, UT, 84111, US

(73) Assignee: NATIONAL CENTRAL UNIVERSITY, Taoyuan (TW)

(21) Appl. No.: 12/471,355

(22) Filed: May 23, 2009

(30) Foreign Application Priority Data
Nov. 26, 2008 (TW) 097145779

(51) Int. Cl. H01L 31/00

(52) U.S. Cl. 136/256

(57) ABSTRACT

A guided mode resonance solar cell includes a solar cell body and a guided mode resonance unit. The solar cell body is used for converting optical energy into electrical energy. The guided mode resonance unit is formed on the solar cell body, and includes a grating structure and a waveguide structure. The grating structure includes multiple sub-wavelength light pillars. When a light emitted from a light source is incident onto the grating structure, a resonant of the light occurs in the grating structure to facilitate trapping the light in the waveguide structure and elongating an optical path length.

### FIELD OF THE INVENTION

The present invention relates to a guided mode resonance solar cell, and more particularly to a guided mode resonance solar cell with enhanced energy conversion efficiency.

### BACKGROUND OF THE INVENTION

Recently, the ecological problems resulted from fossil fuels such as petroleum and coal have been greatly aware all over the world. Consequently, there are growing demands on clean energy. Among various alternative energy sources, a solar cell is expected to replace fossil fuel as a new energy source because it provides clean energy without depletion and is easily handled. A solar cell can convert sunlight directly into electrical energy, which is fed into various power modules for applications.

Nowadays, the technologies and researches relating to applications of the solar cell in producing electricity for practical use are gaining popularity. The solar cell mainly captures energy from sunlight. The solar cell absorbs the visible part of the solar spectrum more strongly. In addition, the solar spectrum covers the ultraviolet light (<4 μm) and the infrared part (>0.7 μm). The most commonly known solar cell is made of silicon because silicon exhibits excellent energy conversion efficiency in the solar spectrum. Depending on the crystal structures, monocrystalline silicon, polycrystalline silicon and amorphous silicon are three types of silicon materials. In views of cost and applications, solar cells with diverse photoelectric properties are produced. Generally, monocrystalline silicon has lower optical absorption coefficient and higher energy conversion efficiency than polycrystalline silicon and amorphous silicon. The fabricating cost of monocrystalline silicon is relatively larger. Although the energy conversion efficiency of polycrystalline silicon is lower than monocrystalline silicon, the fabrication process of polycrystalline silicon is relatively simplified and the use of polycrystalline silicon is more cost-effective.

A solar cell is a semiconductor device that converts sunlight directly into electrical energy by a photovoltaic effect. Take the monocrystalline silicon for example. When a layer of p-type silicon is in intimate contact with a layer of n-type silicon, an electric field is created. When the sunlight with energy above the gap energy between the valence band and the conduction band is absorbed by silicon, an electron-hole pair is generated. The electric field established across the p-n junction promotes a charge flow (known as drift current).

From the above description, it is found that the performance of the solar cell is dependent on the energy conversion efficiency of the photovoltaic effect. Higher energy conversion efficiency hints higher cost. With the maturity of the semiconductor fabricating industries, the demand quantity of silicon gradually increases and thus the cost of silicon becomes relatively costly. The thin-film silicon (TF-Si) solar cell is a promising low-cost approach due to less consumption of silicon material than that in bulk silicon solar cells.

A major challenge in achieving high efficiency TF-Si solar cells is the insufficient absorption for the gap energy between the valence band and the conduction band. The insufficient absorption leads to low energy conversion efficiency. In addition, the light absorbed by the planar thin-film silicon can only be reflected by or transmitted through the planar thin-film silicon. It is found that the insufficient absorption is resulted from small thickness of the thin-film silicon. This problem is especially severe in the near infrared spectrum (about 0.9 μm to 1 μm). The absorption length in the near infrared spectrum should be as large as possible. The key solution is to enhance the optical path length by strongly trapping light within the cell.

For solving poor light absorption in TF-Si solar cells at higher wavelengths, the improvement in light trapping can be realized by two approaches. In accordance with the first approach, the silicon surface is designed to have regular submicron textures (e.g. random pyramids, periodic pyramids and binary gratings) by light refraction or diffraction in order to increase optical path length. In accordance with the second approach, the material that increases the internal reflection is added. The total internal reflection will occur at the front surface of the solar cell and the unabsorbed light is reflected back to the silicon material for further absorption. In general, the submicron textures on the silicon surface are designed at a specific wavelength. As the incident wavelength is away from the specific wavelength, the effect of energy coupling will decay and thus the optical path length fails to be effectively elongated by surface textures. Moreover, as the diffracted wave is reflected by the silicon material, a part of wave will evanesce from the surface textures and can't be returned back to the silicon material again. Therefore, a satisfactory light-trapping effect occurring in thin-film solar cell is achieved only within narrow bandwidths and limited incident angles.

### SUMMARY OF THE INVENTION

The present invention provides a guided mode resonance solar cell by combining a guided mode resonance (GMR) unit with a known TF-Si solar cell body, thereby elongating the optical path length, increasing the light absorption, and enhancing the energy conversion efficiency.

In accordance with an aspect of the present invention, there is provided a guided mode resonance solar cell. The guided mode resonance solar cell includes a solar cell body, a first substrate and a first thin film. The solar cell body is used for converting optical energy into electrical energy. The first substrate has a first surface and a second surface, wherein the first surface of the first substrate is formed on the solar cell body. The first thin film is formed on the second surface of the first substrate, and includes a grating structure and a waveguide structure. The grating structure is formed on the waveguide structure. The grating structure includes multiple first light pillars with a first filling factor and multiple second light pillars with a second filling factor. The first light pillars and the second light pillars are spaced from each other and alternately arranged on the waveguide structure. The sum of the first filling factor and the second filling factor is equal to a half of one period of the grating structure. When a light emitted from a light source is incident onto the first thin film, a resonant of the light occurs in the grating structure to facilitate trapping the light in the waveguide structure to elongate an optical path length, and the light further penetrates through the first substrate to be absorbed by the solar cell body.

In accordance with another aspect of the present invention, there is provided a guided mode resonance solar cell. The guided mode resonance solar cell includes a solar cell body and a guided mode resonance unit. The solar cell body is used for converting optical energy into electrical energy. The guided mode resonance unit is formed on the solar cell body, and includes a grating structure and a waveguide structure. The grating structure includes multiple sub-wavelength light pillars. When a light emitted from a light source is incident onto the grating structure, a resonant of the light occurs in the grating structure to facilitate trapping the light in the waveguide structure and elongating an optical path length.

### BRIEF DESCRIPTION OF THE DRAWINGS

The above contents of the present invention will become more readily apparent to those ordinarily skilled in the art after reviewing the following detailed description and accompanying drawings, in which:

FIG. 1A is a schematic cross-sectional view illustrating a guided mode resonance solar cell according to an embodiment of the present invention;

FIG. 1B is a schematic perspective view illustrating the guided mode resonance solar cell of FIG. 1A; and

FIGS. 2A˜2D schematically illustrate the dynamic behavior of resonant wave in the grating structure by using time-varying energy distributions.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

The present invention provides a guided mode resonance solar cell. The guided mode resonance solar cell combines a guided mode resonance (GMR) unit with a known TF-Si solar cell body. The guided mode resonance solar cell of the present invention has an elongated optical path length and increased light dwelling time, so that the energy conversion efficiency and the light-trapping effect are both enhanced. The term “guided mode resonance (GMR)” is a phenomenon indicating that the light passing through gratings irregularly diffracts into a waveguide layer. That is, the light passing through gratings tends to couple into the waveguide layer and result in a resonant for facilitating trapping the light in the waveguide layer. The guided mode resonance unit is made of silicon material and quartz by a semiconductor fabrication process. Since the guided mode resonance unit could by produce by the same semiconductor fabrication process as the conventional solar cell, the combination of the guided mode resonance unit with the known TF-Si solar cell body is applicable.

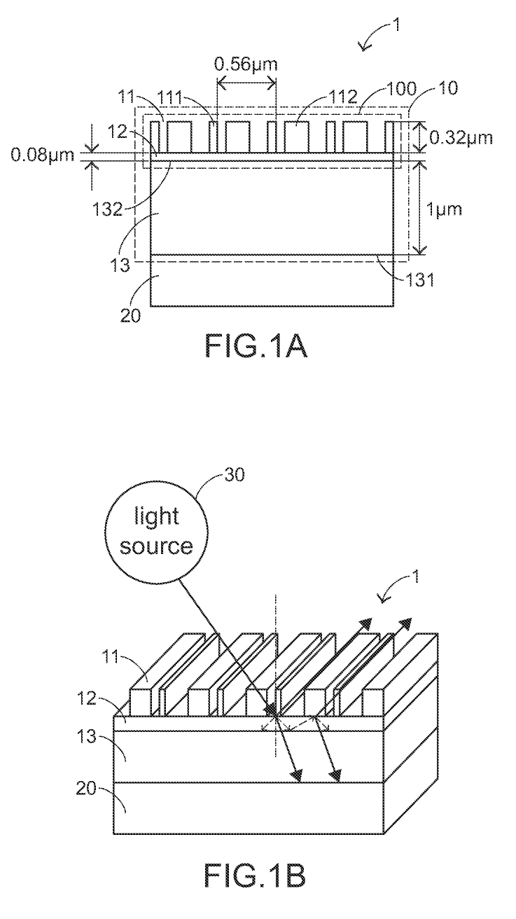

FIG. 1A is a schematic cross-sectional view illustrating a guided mode resonance solar cell according to an embodiment of the present invention. As shown in FIG. 1A, the guided mode resonance solar cell 1 comprises a guided mode resonance unit 10 and a solar cell body 20. The guided mode resonance unit 10 is formed on the solar cell body 20. By the solar cell body 20, optical energy is converted into electrical energy. The solar cell body 20 has the same structure as the solar cell body of the known thin-film silicon solar cell, and thus the fabricating process of the solar cell body 20 is not redundantly described herein. The solar cell body 20 has a planar configuration without any submicron textures (e.g. pyramids or gratings). In addition, the solar cell body 20 is made of silicon, glass or quartz. By a semiconductor fabricating process, the guided mode resonance unit 10 is deposited on the solar cell body 20. In particular, a first surface 131 of a first substrate 13 of the guided mode resonance unit 10 is formed on the solar cell body 20.

It is preferred that the first substrate 13 is made of quartz (refractive index=1.46) or glass. As shown in FIG. 1A, the guided mode resonance unit 10 further comprises a first thin film 100. The first thin film 100 is formed on a second surface 132 of the first substrate 13 by deposition for example. The first thin film 100 is made of polycrystalline silicon (poly-Si) having a refractive index of 3.48. In this embodiment, the first thin film 100 comprises a grating structure 11 and a waveguide structure 12. The grating structure 11 is formed on the waveguide structure 12. In an embodiment, a mask layer is patterned by a photolithography and etching procedure to define the grating structure 11 and the waveguide structure 12.

FIG. 1B is a schematic perspective view illustrating the guided mode resonance solar cell of FIG. 1A. The grating structure 11 is an asymmetric sub-wavelength or submicron structure. In other words, the grating structure 11 includes multiple sub-wavelength or submicron light pillars that are unequally-spaced or asymmetrically arranged. As shown in FIG. 1B, the grating structure 11 includes asymmetric binary gratings with two filling factors. The first light pillar 111 has a first filling factor and the second light pillar 112 has a second filling factor. These two distinct filling factors in a half period are adopted. That is, the sum of the width of the first light pillar 111 and the width of the second light pillar 112 is equal to a half period width of the asymmetric binary gratings. The remainder half period width is equal to the interval between a specified second light pillar 112 and the previous first light pillar 111 plus the interval between the specified second light pillar 112 and the next first light pillar 111. Otherwise, the remainder half period width is equal to the interval between a specified first light pillar 111 and the previous second light pillar 112 plus the interval between the specified first light pillar 111 and the next second light pillar 112. In other words, multiple first light pillars 111 and multiple second light pillars 112 are alternately arranged on the waveguide structure 12, wherein the first light pillar 111 and the second light pillar 112 respectively have the first filling factor and the second filling factor in each half period.

In the guided mode resonance unit 10, the thickness of the first substrate 13 is 1 μm, the thickness of the waveguide structure 12 is 0.08 μm, the depth of the grating structure 11 is 0.32 μm, and the period of the grating structure 11 is 0.56 μm. In the asymmetric structure, the first filling factor is 0.12 in one period of the grating structure 11 and the second filling factor is 0.38 in one period of the grating structure 11. The sum of the first filling factor and the second filling factor is 0.5 in one period of the grating structure 11. In other words, the multiple first light pillars 111 and multiple second light pillars 112 are alternately arranged on the waveguide structure 12, wherein the first filling factor is 0.12 and the second filling factor is 0.38 in one period of the grating structure 11. As such, the grating structure 11 is a guided mode resonance grating structure.

Please refer to FIG. 1B again. A light emitted from a light source 30 is incident onto the guided mode resonance solar cell 1. In practice, the light emitted from a light source 30 is incident onto the first thin film 100 of the guided mode resonance solar cell 1 from all angles. For clarification and brevity, only a specified incidence angle is shown in the drawing. When the light is incident onto the first thin film 100, dynamic behaviors (e.g. reflection, refraction, diffraction and transmission) of the light in the interfaces of the guided mode resonance solar cell 1 are resulted because of the grating structure 11, the waveguide structure 12 and the first substrate 13. Depending on the wavelength or spectral range of the light emitted from the light source 30 and the incidence angles, the dynamic behaviors are varied. As shown in FIG. 1B, a part of light is directly reflected on the first thin film 100. Another part of light diffracts or refracts in the grating structure 11, further propagates transversely in the waveguide structure 12, and finally penetrates through the first substrate 13 to be absorbed by the solar cell body 20.

In accordance with a key feature of the present invention, the light tends to couple into the wider light pillar of the asymmetric sub-wavelength or submicron structure owing to the assistance of thinner light pillar. In addition, due to the arrangement of the alternately spaced sub-wavelength or submicron light pillars, the light tends to diffract into the waveguide structure.

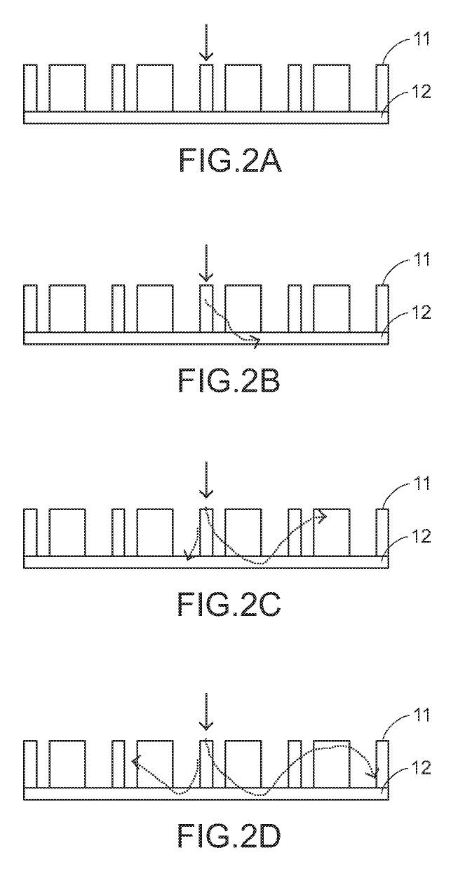

The dynamic behavior of resonant wave in the grating structure is illustrated in FIGS. 2A˜2D by using time-varying energy distributions. The light emitted from the light source is incident onto the grating structure 11 under normal incidence. As shown in FIG. 2A, the light starts to be incident onto the grating structure 11. As shown in FIGS. 2B, 2C and 2D, the light tends to couple into neighboring light pillars in both sides, further propagate transversely in the waveguide structure, and gradually elongate the optical path length between more light pillars in a saw-toothed route. As mentioned above, the light in the diffraction and the resonance mode tends to couple into the wider light pillars owing to the assistance of thinner light pillars. That is, the light tends to couple from the first light pillars 111 into the second light pillars 112. Since the light tends to couple into the next light pillars in the propagation direction, it is also meant that the light tends to couple into the thinner light pillars owing to the assistance of wider light pillars. That is, the light tends to couple from the second light pillars 112 into the first light pillars 111.

The strongly lateral coupling effect caused by the light pillars of the grating structure 11 also offers a wave-guiding property to the grating structure 11. Moreover, the light tends to diffract into the waveguide structure 12 so as to offer a transverse propagation efficacy. Based on the guided mode resonant, the light complying with a resonance mode of a waveguide equation could propagate transversely in the waveguide structure. Once the light enters from the waveguide structure 12 to the grating structure 11, the light will diffract into the waveguide structure 12 again. As a consequence, the optical path length is effectively elongated without escaping into the air.

In this embodiment, since the grating structure 11 is an asymmetric sub-wavelength or submicron structure, the tendency of the light to couple into the neighboring light pillars in the right side and the tendency of the light to couple into the neighboring light pillars in the left side are uneven. In other words, the light tends to propagate in the direction having a stronger lateral coupling effect. If the exposing time is sufficient, diffraction and lateral propagation occur in both sides.

Due to the design of the present invention, the light incident onto the guided mode resonance solar cell exhibits diffraction and transverse propagation efficacy, and thus the optical path length is effectively elongated. Moreover, diffraction and resonance are enhanced for a specified spectral range according to the present invention. In the implementation examples, it is found that the light in a specified spectral range could directly penetrate through the first substrate 13 to be absorbed by the solar cell body 20. The diffraction and resonance generated by the grating structure 11 can effectively elongate the optical path length of the light in the near infrared spectrum (about 0.9 μm to 1 μm).

An experiment demonstrates that the light couples into neighboring light pillars to respectively result in three saw-toothed length path in both sides. That is, the optical path length of the light is elongated in the grating structure 11 by six period widths of the asymmetric binary gratings. Afterwards, the light propagates transversely in the waveguide structure 12. The fraction of the light that does not evanesce to the air will penetrate through the first substrate 13 to be absorbed by the solar cell body 20. In other words, when the light diffracts and transversely propagates between the grating structure 11 and the waveguide structure 12, the optical path length of the light is elongated and thus the dwelling time of the light in the guided mode resonance solar cell 1 is increased. As a consequence, the light absorption and the light-trapping effect are both enhanced.

Another experiment demonstrates that the trapped photon numbers or the light-trapping effect is increased if the light is incident onto the first thin film 100 at the incident angles within the range between −40 and +40 degrees. Moreover, reflection and transmission in different positions of the guided mode resonance solar cell 1 are improved when compared with the conventional planar silicon thin-film solar cell. According to the time-varying energy distributions, when the light in the near infrared spectrum (about 0.9 μm to 1 μm) is incident onto the surface of the first thin film 100, the photon numbers reflected to the air, the photon numbers penetrating through the interface between the first thin film 100 and the second surface 132 of the first substrate 13, and the photon numbers escaping from the first surface 131 of first substrate 13 into the air drop down quickly after a certain exposing time. As a consequence, the dwelling time of the light in the guided mode resonance solar cell 1 is increased and the optical path length of the light is effectively elongated in the lateral sides.

In the above embodiments, the grating structure 11 is illustrated by referring to an asymmetric sub-wavelength or submicron structure. Nevertheless, the grating structure may be designed to have a symmetric structure, wherein the light pillars are equally-spaced and asymmetrically arranged. In a case that the symmetric grating structure is disposed on the solar cell body 20, the light-trapping effect is also obviously enhanced. With the proviso that the guided mode resonance occurs, the dimension of the asymmetric grating structure 11 or other parameters are adjustable. For example, the thickness of the waveguide structure 12, the depth of the grating structure 11, the period of the grating structure 11 and the fractions of the first and second filling factors are adjustable according to the practical requirements. In a case that the symmetric grating structure having the adjusted parameters is disposed on the solar cell body 20, the light-trapping effect is also obviously enhanced.

From the above description, the guided mode resonance solar cell combines a guided mode resonance (GMR) unit with a known solar cell body. In comparison with the conventional planar silicon thin-film solar cell only capable of reflecting or transmitting light, the guided mode resonance solar cell of the present invention has an elongated optical path length and increased light dwelling time, so that the energy conversion efficiency and the light-trapping effect are both enhanced. As previously, the pyramids or the gratings on the surface of the conventional solar cell are designed to elongate the optical path length at a specific wavelength. Whereas, due to the enhanced coupling effect and diffraction, the guided mode resonance solar cell of the present invention can effectively elongate the optical path length of the light in the near infrared spectrum (about 0.9 μm to 1 μm). Since the light absorption in the guided mode resonance solar cell of the present invention is increased, the energy conversion efficiency is increased. The guided mode resonance solar cell of the present invention has increased light absorption and energy conversion efficiency, thereby obviating the drawbacks encountered from the prior art.

While the invention has been described in terms of what is presently considered to be the most practical and preferred embodiments, it is to be understood that the invention needs not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A guided mode resonance solar cell, comprising:
a solar cell body for converting optical energy into electrical energy;
a first substrate having a first surface and a second surface, wherein the first surface of the first substrate is formed on the solar cell body; and
a first thin film formed on the second surface of the first substrate, and including a grating structure and a waveguide structure, wherein the grating structure is formed on the waveguide structure, the grating structure includes multiple first light pillars with a first filling factor and multiple second light pillars with a second filling factor, the first light pillars and the second light pillars are spaced from each other and alternately arranged on the waveguide structure, and the sum of the first filling factor and the second filling factor is equal to a half of one period of the grating structure,
wherein when a light emitted from a light source is incident onto the first thin film, a resonant of the light occurs in the grating structure to facilitate trapping the light in the waveguide structure to elongate an optical path length, and the light further penetrates through the first substrate to be absorbed by the solar cell body.

2. The guided mode resonance solar cell according to claim 1 wherein the light emitted from the light source is absorbed by the solar cell body and converted into electrical energy by the solar cell body.

3. The guided mode resonance solar cell according to claim 1 wherein the first substrate is made of quartz and the first thin film is made of silicon.

4. The guided mode resonance solar cell according to claim 1 wherein the thickness of the first substrate is 1 μm.

5. The guided mode resonance solar cell according to claim 1 wherein the thickness of the waveguide structure is 0.08 μm.

6. The guided mode resonance solar cell according to claim 1 wherein the depth of the grating structure is 0.32 μm.

7. The guided mode resonance solar cell according to claim 1 wherein the period of the grating structure is 0.56 μm.

8. The guided mode resonance solar cell according to claim 1 wherein the first filling factor is 0.12 in one period of the grating structure and the second filling factor is 0.38 in one period of the grating structure.

9. The guided mode resonance solar cell according to claim 1 wherein the resonant of the light occurring in the grating structure facilitates the light to couple from the first light pillars into the second light pillars or from the second light pillars into the first light pillars.

10. The guided mode resonance solar cell according to claim 1 wherein the resonant occurring in the grating structure is resulted from the light within a near infrared spectrum.

11. The guided mode resonance solar cell according to claim 1 wherein the light emitted from the light source is permitted to penetrate through the first substrate, diffract into the grating structure, or be reflected by the first thin film.

12. The guided mode resonance solar cell according to claim 1 wherein when the light emitted from the light source enters the waveguide structure, the light complying with a resonance mode of a waveguide equation is permitted to propagate transversely in the waveguide structure to elongate the optical path length.

13. A guided mode resonance solar cell, comprising:
a solar cell body for converting optical energy into electrical energy; and
a guided mode resonance unit formed on the solar cell body, and including a grating structure and a waveguide structure, the grating structure including multiple sub-wavelength light pillars, wherein when a light emitted from a light source is incident onto the grating structure, a resonant of the light occurs in the grating structure to facilitate trapping the light in the waveguide structure and elongating an optical path length.

14. The guided mode resonance solar cell according to claim 13 wherein the guided mode resonance unit further includes a first substrate formed on the solar cell body, and the waveguide structure is formed on the first substrate.

15. The guided mode resonance solar cell according to claim 13 wherein the grating structure is formed on the waveguide structure.

16. The guided mode resonance solar cell according to claim 13 wherein the multiple sub-wavelength light pillars include multiple first light pillars with a first filling factor and multiple second light pillars with a second filling factor, and the first light pillars and the second light pillars are spaced from each other and alternately arranged on the waveguide structure.

17. The guided mode resonance solar cell according to claim 16 wherein the sum of the first filling factor and the second filling factor is equal to a half of one period of the grating structure.

18. The guided mode resonance solar cell according to claim 16 wherein the resonant of the light occurring in the grating structure facilitates the light to couple from the first light pillars into the second light pillars or from the second light pillars into the first light pillars.

19. The guided mode resonance solar cell according to claim 13 wherein the grating structure and the waveguide structure are made of silicon thin film material and the first substrate is made of quartz.
